(19) United States
(12) Patent Application Publication
(10) Pub. No.: US 2026/0033347 A1
(43) Pub. Date: Jan. 29, 2026

(54) SEMICONDUCTOR PACKAGE CARRIER STRUCTURE AND MANUFACTURING METHOD THEREOF

(71) Applicant: PHOENIX PIONEER TECHNOLOGY CO., LTD., Hsinchu County (TW)

(72) Inventors: Chao-Ching Tseng, Hsinchu County (TW); Che-Wei HSU, Hsinchu County (TW); Shih-Ping HSU, Hsinchu County (TW)

(21) Appl. No.: 19/277,291

(22) Filed: Jul. 22, 2025

(30) Foreign Application Priority Data
Jul. 29, 2024 (TW) 113128133

(51) Int. Cl. H01L 23/495; H01L 21/48

(52) U.S. Cl. CPC H01L 23/49541; H01L 21/4821; H01L 23/49503; H01L 23/49582; H01L 23/49586

(57) ABSTRACT

A semiconductor package carrier structure is provided and includes a substrate body, a dielectric material, and a patterned circuit layer. The substrate body has a plurality of openings, a plurality of conductive pillars, and at least one die placement portion. The dielectric material is disposed in the plurality of openings. The patterned circuit layer is disposed on a surface of the substrate body. Side surfaces of the plurality of conductive pillars and the die placement portion are all in a concave arc shape. The patterned circuit layer includes a die placement pad corresponding to the die placement portion and a plurality of bonding pads corresponding to the plurality of conductive pillars. A method of manufacturing the semiconductor package carrier structure is further provided.

### BACKGROUND

### 1. Technical Field

The present disclosure relates to a semiconductor package carrier structure, and more particularly, to a semiconductor package carrier structure having a single-side etching and a substrate structure bonded to a patterned circuit layer and a manufacturing method thereof.

### 2. Description of Related Art

With the advancement of semiconductor packaging technology, various packaging types for semiconductor devices have been developed for products such as smartphones, tablet computers, network equipment, and laptops. For example, different packaging types such as ball grid array (BGA), quad flat package (QFP), or quad flat no-lead (QFN) semiconductor packages have been introduced.

FIG. 1 is a schematic view of a conventional lead frame package carrier structure 1. As shown in FIG. 1, the conventional lead frame package carrier structure 1 comprises: a substrate 10 having a first surface 10a and a second surface 10b opposite to the first surface 10a, a circuit layer 11 formed on the first surface 10a of the substrate 10, a conductive pillar 12 formed in the substrate 10, a surface treatment layer 13 formed on the circuit layer 11 and/or the conductive pillar 12, and a dielectric layer 14 formed on the second surface 10b of the substrate 10, wherein the substrate 10 is a copper plate.

Specifically, the first surface 10a and the second surface 10b of the substrate 10 are half-etched on both sides to form a double-sided etched structure. Then, the circuit layer 11 and the conductive pillar 12 are formed. After a separation process is performed, the surface treatment layer 13 is formed on the first surface 10a of the substrate 10, and the dielectric layer 14 is laminated into the substrate 10 from the second surface 10b by a lamination process. Accordingly, the lead frame package carrier structure 1 is completed.

However, in the manufacturing process of the conventional lead frame package carrier structure 1, the etching depth and side etching produced by the double-sided half etching process are difficult to control, thereby resulting in poor consistency of the lead frame package carrier structure 1 with a double-sided etched structure. This will severely affect the electrical quality and cause the yield to be unstable during production and manufacturing, failing to meet specification requirements, thereby limiting the flexibility of product design.

Furthermore, the conventional lead frame package carrier structure has poor routing capability and is not suitable for multi-chip packaging.

Therefore, how to avoid the various deficiencies in the prior art has become a problem that needs to be solved urgently.

### SUMMARY

To solve the above-mentioned problems, the present disclosure provides a semiconductor package carrier structure, which comprises: a substrate body being a plate body made of a conductive material and having a first surface and a second surface opposite to the first surface, wherein the substrate body has a plurality of openings penetrating through the substrate body to define at least one die placement portion and a plurality of conductive pillars distributed around the die placement portion, wherein side surfaces of the die placement portion and the plurality of conductive pillars are in a concave arc shape; a dielectric material formed in the plurality of openings, wherein portions of surfaces of the dielectric material are exposed from the first surface and the second surface; and a patterned circuit layer disposed on one of the first surface or the second surface of the substrate body, wherein the patterned circuit layer comprises a die placement pad corresponding to the die placement portion and a plurality of bonding pads corresponding to the plurality of conductive pillars, wherein the die placement pad and the die placement portion are electrically connected to each other, and a portion of the plurality of bonding pads and a portion of the plurality of conductive pillars are electrically connected to each other.

In one specific embodiment, the present disclosure further comprises: a metallization layer disposed between the die placement pad and the die placement portion, between the bonding pads and the conductive pillars, and between some of the plurality of bonding pads and the portions of the dielectric material.

In one specific embodiment, the present disclosure further comprises: a metallization layer disposed between inner wall surfaces of the plurality of openings of the substrate body and the dielectric material, and between some of the plurality of bonding pads and the portions of the dielectric material.

In one specific embodiment, the dielectric material covers the first surface or the second surface of the substrate body, and the patterned circuit layer is disposed on the dielectric material of the first surface or the second surface of the substrate body, wherein portions of the patterned circuit layer are electrically connected to the die placement portion and the plurality of conductive pillars via a plurality of conductive blind vias embedded in the dielectric material, and a metallization layer is disposed between the patterned circuit layer and the dielectric material, and on side surfaces and bottom surfaces of the plurality of conductive blind vias.

In one specific embodiment, the metallization layer is at least one selected from a group consisting of a chemically deposited copper layer, a sputtered titanium layer, and a sputtered copper layer.

In one specific embodiment, the package applications of the semiconductor package carrier structure include at least one electronic element disposed on the die placement pad and electrically connected to the plurality of bonding pads; and a packaging layer disposed on the substrate body and encapsulating the patterned circuit layer and the electronic element.

The present disclosure also provides a method of manufacturing a semiconductor package carrier structure, and the method comprises: providing a substrate body, wherein the substrate body has a first surface and a second surface opposite to the first surface, and the substrate body is made of a conductive material; bonding the second surface of the substrate body to a carrying plate; forming a plurality of openings penetrating through the substrate body on the first surface of the substrate body by etching via a patterned exposure, development and etching process to define at least one die placement portion and a plurality of conductive pillars distributed around the die placement portion, wherein side surfaces of the die placement portion and the plurality of conductive pillars are in a concave arc shape; forming a dielectric material on the first surface of the substrate body to fill the plurality of openings and cover the first surface of the substrate body; performing a planarization process to remove portions of the dielectric material to expose the first surface of the substrate body; removing the carrying plate to expose the second surface of the substrate body and portions of a surface of the dielectric material; and forming a patterned circuit layer by electroplating on the first surface or the second surface of the substrate body and the exposed surface of the dielectric material via a patterned exposure, development and electroplating process, wherein the patterned circuit layer comprises a die placement pad corresponding to the die placement portion and a plurality of bonding pads corresponding to the plurality of conductive pillars, wherein the die placement pad is electrically connected to the die placement portion, and the plurality of bonding pads are electrically connected to the plurality of conductive pillars.

In one specific embodiment, before performing the patterned exposure, development and electroplating process, the present disclosure further comprises: forming a metallization layer on the first surface or the second surface of the substrate body and the exposed surface of the dielectric material by a chemical deposition process; and performing an etching process after the patterned exposure, development and electroplating process is completed to form the patterned circuit layer on a surface of the metallization layer, so as to remove portions of the metallization layer that are not covered by the patterned circuit layer, thereby exposing portions of the first surface or the second surface and portions of a surface of the dielectric material.

In one specific embodiment, before forming the dielectric material, the present disclosure further comprises: forming a metallization layer on the first surface of the substrate body and inner wall surfaces and bottom surfaces of the plurality of openings by a chemical deposition process; and performing an etching process after the patterned exposure, development and electroplating process is completed on the metallization layer and the second surface, and the patterned circuit layer is formed on the metallization layer and the second surface, so as to remove portions of the metallization layer that are not covered by the patterned circuit layer and to remove portions of the conductive material on the second surface of the substrate body, thereby exposing portions of a surface of the dielectric material.

In one specific embodiment, performing the planarization process results in that the first surface of the substrate body is not exposed, and the present disclosure further comprises: performing an opening process to remove portions of the dielectric material, so as to form a plurality of recessed openings on a surface of the dielectric material, wherein end surfaces of the die placement portion and the plurality of conductive pillars are exposed; performing a chemical deposition process to form a metallization layer on the surface of the dielectric material and in the plurality of openings; and performing an etching process after completing the patterned exposure, development and electroplating process to form the patterned circuit layer on the surface of the metallization layer and forming a plurality of conductive blind vias in the plurality of openings, so as to remove portions of the metallization layer that are not covered by the patterned circuit layer and expose portions of the surface of the dielectric material.

In one specific embodiment, the metallization layer is at least one selected from a group consisting of a chemically deposited copper layer, a sputtered titanium layer, and a sputtered copper layer.

In one specific embodiment, the opening process includes laser removal, exposure and development removal, etching removal, plasma removal, or drilling removal to form the plurality of openings.

In one specific embodiment applied to semiconductor packaging, the present disclosure further comprises: disposing and bonding an electronic element to the die placement pad, and electrically connecting the electronic element to the plurality of bonding pads; and forming a packaging layer on the substrate body to encapsulate the patterned circuit layer and the electronic element.

In the aforementioned semiconductor package carrier structure and method, the present disclosure further comprises: a surface treatment layer disposed on the patterned circuit layer.

In some specific embodiments of the aforementioned semiconductor package carrier structure and method, the conductive material forming the substrate body is at least one selected from a group consisting of pure copper, copper alloy, and nickel alloy.

In some specific embodiments of the aforementioned semiconductor package carrier structure and method, the dielectric material comprises a photosensitive organic dielectric material or a non-photosensitive organic dielectric material. In some specific embodiments, the dielectric material is at least one selected from a group consisting of Ajinomoto build-up film, polybenzoxazole, polyimide, prepreg with glass fibers, epoxy, epoxy molding compound, and bismaleimide triazine.

As can be seen from the above, the present disclosure utilizes a single-sided etching combined with a single-sided electroplating process to define a plurality of conductive pillars and a die placement portion having side surfaces in a concave arc shape on the substrate body, and to form a patterned circuit layer, including a die placement pad corresponding to the die placement portion and a plurality of bonding pads corresponding to the plurality of conductive pillars, on the substrate body, thereby obtaining a semiconductor package carrier structure. Therefore, compared with the prior art, the present disclosure can improve the instability of the double-sided etched lead frame package carrier structure, and can greatly improve the yield of the semiconductor package carrier structure, and effectively improve the extensiveness of product application design.

### BRIEF DESCRIPTION OF THE DRAWINGS

FIG. 1 is a schematic view of a conventional lead frame package carrier structure.

FIG. 2A to FIG. 2G are cross-sectional schematic views illustrating a method for manufacturing a semiconductor package carrier structure according to a first embodiment of the present disclosure.

FIG. 3A to FIG. 3F are cross-sectional schematic views illustrating a method for manufacturing a semiconductor package carrier structure according to a second embodiment of the present disclosure.

FIG. 4A to FIG. 4D are cross-sectional schematic views illustrating a method for manufacturing a semiconductor package carrier structure according to a third embodiment of the present disclosure.

FIG. 5A to FIG. 5F are cross-sectional schematic views illustrating a method for manufacturing a semiconductor package carrier structure according to a fourth embodiment of the present disclosure.

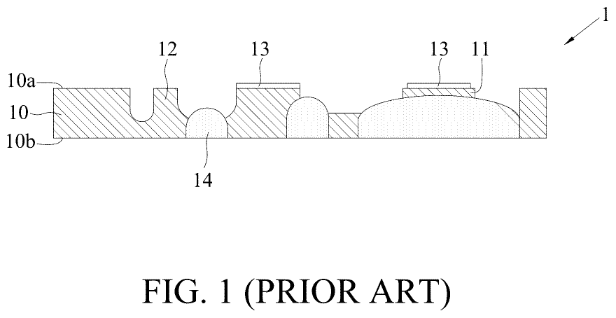

### DETAILED DESCRIPTION

The following describes the implementation of the present disclosure with examples. Those skilled in the art can easily understand other advantages and effects of the present disclosure from the contents disclosed in this specification.

It should be understood that, the structures, ratios, sizes, and the like in the accompanying figures are used for illustrative purposes to facilitate the perusal and comprehension of the contents disclosed in the present specification by one skilled in the art, rather than to limit the conditions for practicing the present disclosure. Any modification of the structures, alteration of the ratio relationships, or adjustment of the sizes without affecting the possible effects and achievable proposes should still be deemed as falling within the scope defined by the technical contents disclosed in the present specification. Meanwhile, terms such as “a,” “one,” “first,” “second,” “on,” “upper,” “lower,” and the like used herein are merely used for clear explanation rather than limiting the practicable scope of the present disclosure, and thus, alterations or adjustments of the relative relationships thereof without essentially altering the technical contents should still be considered in the practicable scope of the present disclosure.

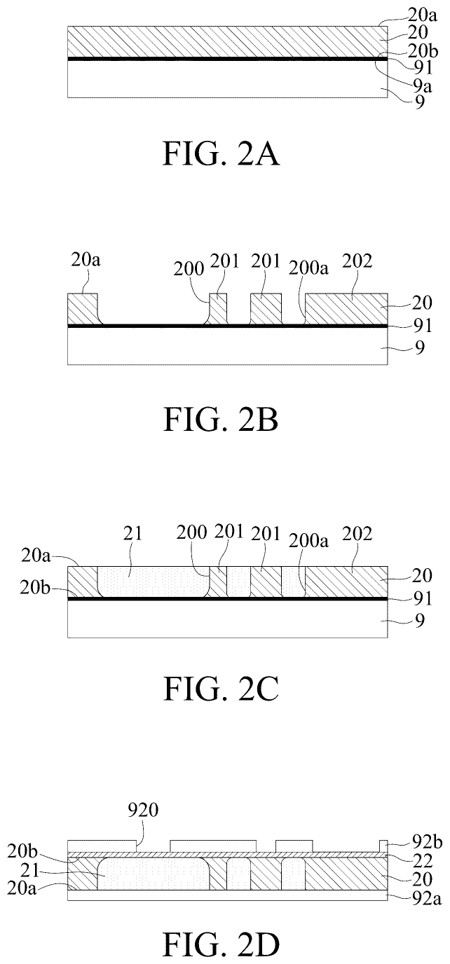

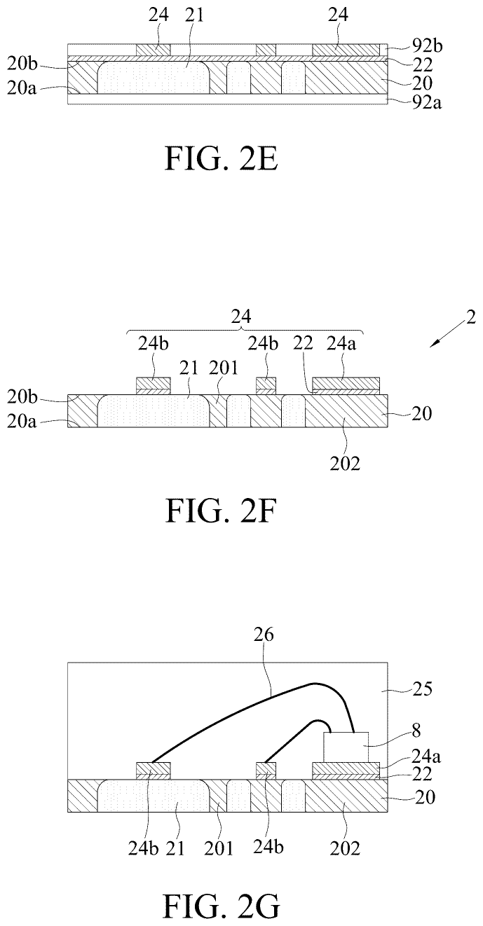

FIG. 2A to FIG. 2G are cross-sectional schematic views illustrating a method for manufacturing a semiconductor package carrier structure 2 according to a first embodiment of the present disclosure.

As shown in FIG. 2A, a carrying plate 9 is provided, and a substrate body 20 is disposed on a surface 9a of the carrying plate 9.

In one embodiment, the substrate body 20 has a first surface 20a and a second surface 20b opposite to the first surface 20a, and a bonding layer 91 is formed on the surface 9a of the carrying plate 9, so that the second surface 20b of the substrate body 20 is disposed on the bonding layer 91, wherein the conductive material forming the substrate body 20 is, for example, at least one selected from a group consisting of pure copper, copper alloy, and nickel alloy. Furthermore, the carrying plate 9 is a temporary carrying plate with appropriate rigidity, and the bonding layer 91 is an adhesive layer with adhesiveness, wherein the bonding layer 91 allows the substrate body 20 to adhere to the surface 9a of the carrying plate 9.

As shown in FIG. 2B, a plurality of openings 200 are formed on the substrate body 20 and penetrate through the first surface 20a and the second surface 20b of the substrate body 20 to define a plurality of conductive pillars 201 and at least one die placement portion 202. The conductive pillars 201 are distributed around the die placement portion 202.

In one embodiment, a patterned exposure, development and etching process is used to etch the first surface 20a of the substrate body 20 to form the plurality of openings 200, so as to penetrate through the first surface 20a and the second surface 20b of the substrate body 20. For example, a dry film photoresist layer (not shown) may be formed on the first surface 20a of the substrate body 20 according to design requirements. Then, portions of the substrate body 20 not covered by the dry film photoresist layer are removed by a stripping process. Thereafter, the dry film photoresist layer is removed after forming the plurality of openings 200, and side surfaces of the resulted plurality of conductive pillars 201 and the die placement portion 202 are in a concave arc shape 200a.

As shown in FIG. 2C, a dielectric material 21 is formed and filled in the plurality of openings 200 of the substrate body 20, wherein portions of end surfaces of the dielectric material 21 are exposed from the first surface 20a and the second surface 20b, and are flush with or not higher than the first surface 20a and the second surface 20b.

Specifically, the dielectric material 21 can be filled into the plurality of openings 200 and covered on the substrate body 20 by vacuum lamination or hot pressing, that is, the dielectric material 21 is formed on the first surface 20a of the substrate body 20. Next, a planarization process is performed to remove portions of the dielectric material 21 by, for example, grinding, so that the first surface 20a (the top surface as shown in FIG. 2C) of the substrate body 20 is exposed from the dielectric material 21. Reactive-ion etching (RIE), plasma etching, chemical etching, etc. may also be used to partially remove the dielectric material 21, or the dielectric material 21 may be partially removed by exposure and development. The method for removing the dielectric material 21 is not limited to any specific procedure.

In one embodiment, the dielectric material 21 comprises a photosensitive organic dielectric material or a non-photosensitive organic dielectric material. In one embodiment, the dielectric material 21 is at least one selected from the group consisting of Ajinomoto build-up film (ABF), polybenzoxazole (PBO), polyimide (PI), prepreg (PP) with glass fibers, epoxy, epoxy molding compound (EMC), and bismaleimide triazine (BT).

As shown in FIG. 2D, the carrying plate 9 and the bonding layer 91 are removed to expose the second surface 20b of the substrate body 20 and portions of the surface of the dielectric material 21. At this point, a semi-finished product of the semiconductor package carrier structure 2 is formed. A metallization layer 22 is formed on the second surface 20b of the substrate body 20 by a patterning process, and a first dry film photoresist layer 92a and a second dry film photoresist layer 92b are formed on the first surface 20a of the substrate body 20 and on the metallization layer 22, respectively.

In one embodiment, all manufacturing processes for completing the semi-finished product of the semiconductor package carrier structure 2 can be performed simultaneously on the upper and lower surfaces of the carrying plate 9, thereby doubling the production capacity.

In one embodiment, the metallization layer 22 can be at least one selected from the group consisting of a chemically deposited copper layer (an electrolessly deposited copper layer), a sputtered titanium layer, and a sputtered copper layer. Furthermore, a patterning process (such as a dry film process) is used to form the first dry film photoresist layer 92a on the first surface 20a of the substrate body 20, and to form the second dry film photoresist layer 92b on the metallization layer 22. The second dry film photoresist layer 92b is a patterned dry film photoresist layer having a plurality of first openings 920, so that portions of the metallization layer 22 are exposed from the second dry film photoresist layer 92b.

As shown in FIG. 2E, a patterned circuit layer 24 is formed by electroplating in the plurality of first openings 920 via a patterned exposure, development and electroplating process.

As shown in FIG. 2F, the first dry film photoresist layer 92a and the second dry film photoresist layer 92b can be removed by a stripping process, and portions of the metallization layer 22 that are not covered by the patterned circuit layer 24 can be removed by etching. Furthermore, portions of the second surface 20b and portions of the surface of the dielectric material 21 are exposed, thereby completing a semiconductor package carrier structure 2. Specifically, the patterned circuit layer 24 comprises a die placement pad 24a corresponding to the die placement portion 202, and a plurality of bonding pads 24b corresponding to the plurality of conductive pillars 201. The die placement pad 24a is electrically connected to the die placement portion 202, and the plurality of bonding pads 24b are electrically connected to the plurality of conductive pillars 201.

In one embodiment, a surface treatment layer (not shown) may be formed entirely or selectively on one or both sides (i.e., on the conductive material of either or both of the opposing surfaces) of the substrate body 20 of the semiconductor package carrier structure 2. Examples of such surface treatments include electroless nickel electroless palladium immersion gold (ENEPIG), nickel/gold electroplating, pre-plating treatment (PPF), or an anti-oxidation layer.

As shown in FIG. 2G, an electronic element 8 is disposed on and bonded to the die placement pad 24a of the semiconductor package carrier structure 2, and the electronic element 8 is electrically connected to the plurality of bonding pads 24b by, for example, bonding wires 26. A packaging layer 25 is then formed on the semiconductor package carrier structure 2 to encapsulate the patterned circuit layer 24 and the electronic element 8, thereby completing a semiconductor package. The semiconductor package can also be completed by using a flip-chip packaging process.

In one embodiment, the electronic element 8 is an active element, a passive element, or a combination of the active element and the passive element, wherein the active element is, for example, a semiconductor chip, and the passive element is, for example, a resistor, a capacitor, an inductor, or a sensing element.

Furthermore, the composition of the packaging layer 25 includes a photosensitive organic dielectric material or a non-photosensitive organic dielectric material. In one embodiment, the composition of the packaging layer 25 is at least one selected from the group consisting of Ajinomoto build-up film (ABF), polybenzoxazole (PBO), polyimide (PI), prepreg (PP) with glass fibers, epoxy, epoxy molding compound (EMC), and bismaleimide triazine (BT).

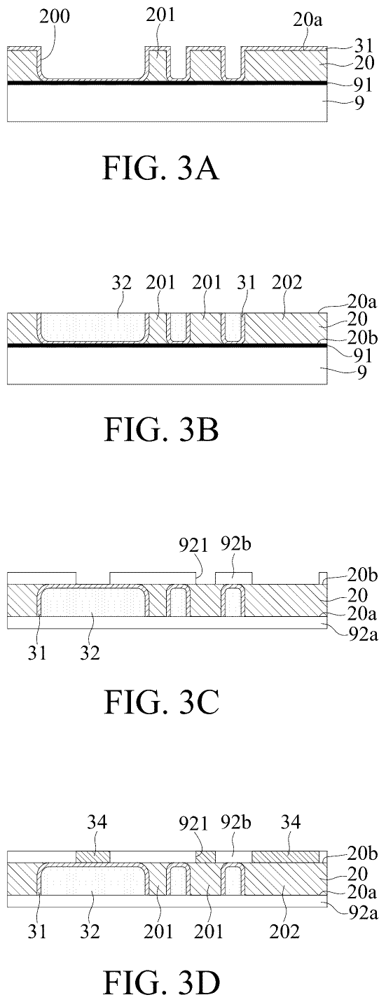

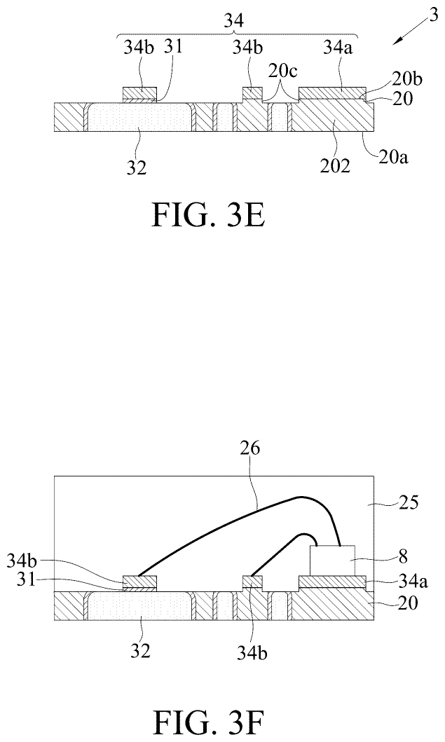

FIG. 3A to FIG. 3F are cross-sectional schematic views illustrating a method for manufacturing a semiconductor package carrier structure 3 according to a second embodiment of the present disclosure, wherein the present embodiment follows the steps of FIG. 2B, so the similarities with the above embodiments will not be restated below.

As shown in FIG. 3A, before forming the dielectric material 32, a metallization layer 31 of a chemically deposited copper layer (an electrolessly deposited copper layer), a sputtered titanium layer, or a sputtered copper layer is formed on the first surface 20a of the substrate body 20, inner wall surfaces and bottom surfaces of the openings 200 by a chemical deposition process.

As shown in FIG. 3B, a dielectric material 32 is formed on the metallization layer 31 in the plurality of openings 200 of the substrate body 20.

In one embodiment, the dielectric material 32 is covered on the metallization layer 31 by vacuum lamination or hot pressing to fill the plurality of openings 200. A planarization process is then performed to remove portions of the dielectric material 32 and portions of the metallization layer 31 by grinding, so that the first surface 20a of the substrate body 20 is exposed from the dielectric material 32 and the metallization layer 31. Reactive-ion etching (RIE), plasma etching, chemical etching, etc. may also be used to remove portions of the dielectric material 32, or portions of the dielectric material 32 may be removed by exposure and development. The method for removing the dielectric material 32 is not limited to any specific procedure.

As shown in FIG. 3C, the carrying plate 9 and the bonding layer 91 are removed to expose the second surface 20b of the substrate body 20. The first dry film photoresist layer 92a is formed on the first surface 20a of the substrate body 20, and the second dry film photoresist layer 92b is formed on the metallization layer 31 and the second surface 20b of the substrate body 20.

In one embodiment, a patterning process (such as a dry film process) is used to form the first dry film photoresist layer 92a on the first surface 20a of the substrate body 20, and to form the second dry film photoresist layer 92b on the metallization layer 31 and the second surface 20b of the substrate body 20. The second dry film photoresist layer 92b is a patterned dry film photoresist layer having a plurality of second openings 921, so that portions of the metallization layer 31 and portions of the substrate body 20 are exposed from the second dry film photoresist layer 92b.

As shown in FIG. 3D, a patterned circuit layer 34 is formed by electroplating in the plurality of second openings 921 and on a portion of the metallization layer 31 via a patterned exposure, development and electroplating process.

As shown in FIG. 3E, the first dry film photoresist layer 92a and the second dry film photoresist layer 92b can be removed by a stripping process, and portions of the metallization layer 31 that are not covered by the patterned circuit layer 34 and portions of the conductive material on the second surface 20b of the substrate body 20 can be removed by etching, so as to expose portions of the surface of the dielectric material 32. The die placement portion 202 has a protrusion 20c corresponding to the die placement pad 34a, and some of the conductive pillars 201 also have a protrusion 20c corresponding to the bonding pad 34b, and the patterned circuit layer 34 comprises a die placement pad 34a corresponding to the die placement portion 202 and a plurality of bonding pads 34b corresponding to the plurality of conductive pillars 201. A semiconductor package carrier structure 3 is thus completed. The die placement pad 34a is electrically connected to the die placement portion 202, and the plurality of bonding pads 34b are electrically connected to the plurality of conductive pillars 201.

In one embodiment, a surface treatment layer (not shown) may be formed entirely or selectively on one or both sides (i.e., on the conductive material of either or both of the opposing surfaces) of the substrate body 20 of the semiconductor package carrier structure 3. Examples of such surface treatments include electroless nickel electroless palladium immersion gold (ENEPIG), nickel/gold electroplating, pre-plating treatment (PPF), or an anti-oxidation layer.

As shown in FIG. 3F, the electronic element 8 is disposed on and bonded to the die placement pad 34a of the semiconductor package carrier structure 3, and the electronic element 8 is electrically connected to the plurality of bonding pads 34b by, for example, bonding wires 26. The packaging layer 25 is then formed on the semiconductor package carrier structure 3 to encapsulate the patterned circuit layer 34 and the electronic element 8, thereby completing a semiconductor package. The semiconductor package can also be completed by using a flip-chip packaging process.

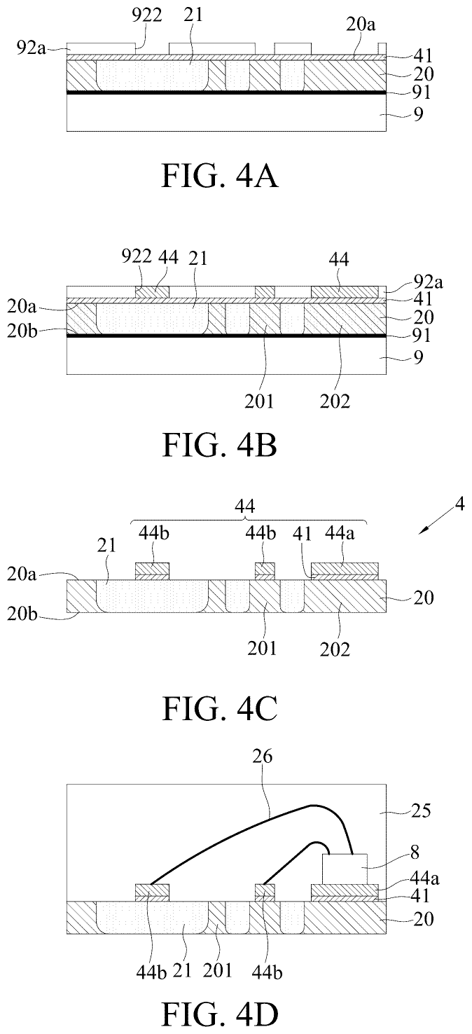

FIG. 4A to FIG. 4D are cross-sectional schematic views illustrating a method for manufacturing a semiconductor package carrier structure 4 according to a third embodiment of the present disclosure, wherein the present embodiment follows the steps of FIG. 2C, so the similarities with the above embodiments will not be restated below.

As shown in FIG. 4A, a metallization layer 41 is formed on the first surface 20a of the substrate body 20 and the exposed surfaces of the dielectric material 21 by a chemical deposition process, and then a first dry film photoresist layer 92a is formed on the metallization layer 41.

In one embodiment, the metallization layer 41 can be at least one selected from the group consisting of a chemically deposited copper layer (an electrolessly deposited copper layer), a sputtered titanium layer, and a sputtered copper layer. Furthermore, a patterning process (such as a dry film process) is used to form the first dry film photoresist layer 92a on the metallization layer 41. The first dry film photoresist layer 92a is a patterned dry film photoresist layer having a plurality of third openings 922, so that portions of the metallization layer 41 are exposed from the plurality of third openings 922 of the first dry film photoresist layer 92a.

As shown in FIG. 4B, a patterned circuit layer 44 is formed by electroplating in the plurality of third openings 922 and on portions of the metallization layer 41 via a patterned exposure, development and electroplating process.

As shown in FIG. 4C, the carrying plate 9 and the bonding layer 91 are removed. Then, the first dry film photoresist layer 92a is removed by a stripping process, and the portions of the metallization layer 41 not covered by the patterned circuit layer 44 are removed by etching, thereby exposing portions of the first surface 20a and portions of the surface of the dielectric material 21. Accordingly, a semiconductor package carrier structure 4 is completed. Specifically, the patterned circuit layer 44 comprises a die placement pad 44a corresponding to the die placement portion 202, and a plurality of bonding pads 44b corresponding to the plurality of conductive pillars 201. The die placement pad 44a is electrically connected to the die placement portion 202, and the plurality of bonding pads 44b are electrically connected to the plurality of conductive pillars 201.

In one embodiment, a surface treatment layer (not shown) may be formed entirely or selectively on one or both sides (i.e., on the conductive material of either or both of the opposing surfaces) of the substrate body 20 of the semiconductor package carrier structure 4. Examples of such surface treatments include electroless nickel electroless palladium immersion gold (ENEPIG), nickel/gold electroplating, pre-plating treatment (PPF), or an anti-oxidation layer.

As shown in FIG. 4D, the electronic element 8 is disposed on and bonded to the die placement pad 44a of the semiconductor package carrier structure 4, and the electronic element 8 is electrically connected to the plurality of bonding pads 44b by, for example, bonding wires 26. The packaging layer 25 is then formed on the semiconductor package carrier structure 4 to encapsulate the patterned circuit layer 44 and the electronic element 8, thereby completing a semiconductor package. The semiconductor package can also be completed by using a flip-chip packaging process.

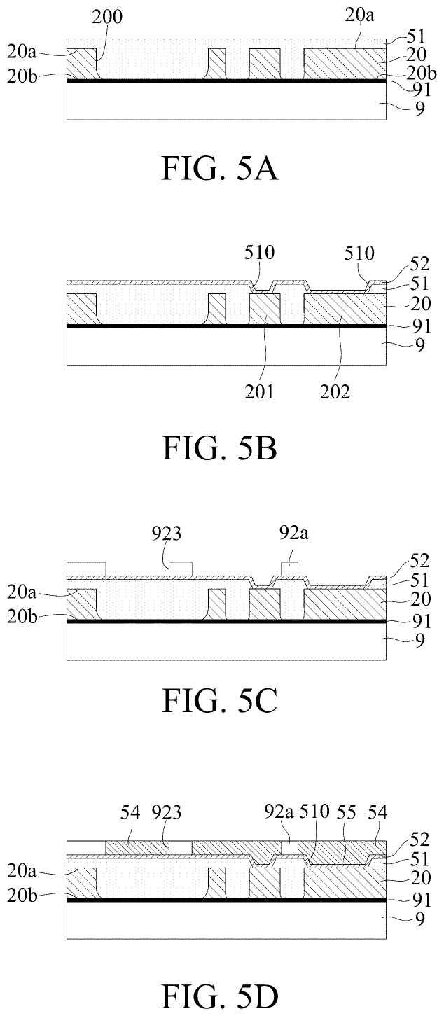

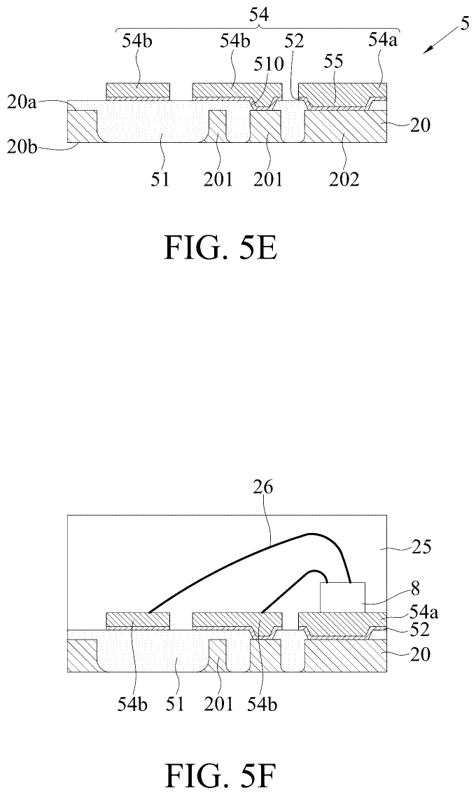

FIG. 5A to FIG. 5F are cross-sectional schematic views illustrating a method for manufacturing a semiconductor package carrier structure 5 according to a fourth embodiment of the present disclosure, wherein the present embodiment follows the steps of FIG. 2B, so the similarities with the above embodiments will not be restated below.

As shown in FIG. 5A, a dielectric material 51 is formed in the plurality of openings 200 of the substrate body 20 and covers the first surface 20a of the substrate body 20.

In one embodiment, the dielectric material 51 is covered on the first surface 20a of the substrate body 20 by vacuum lamination or hot pressing to fill the plurality of openings 200. A planarization process is then performed to remove portions of the dielectric material 51 by grinding to make the dielectric material 51 thinner, and the first surface 20a of the substrate body 20 is not exposed. Reactive-ion etching (RIE), plasma etching, chemical etching, etc. may also be used to remove portions of the dielectric material 51, or portions of the dielectric material 51 may be removed by exposure and development. The method for removing the dielectric material 51 is not limited to any specific procedure.

As shown in FIG. 5B, a plurality of concave fourth openings 510 are formed on the surface of the dielectric material 51 by etching, exposure and development, laser, plasma, or drilling, so as to expose the die placement portion 202 (e.g., an end surface of the die placement portion 202) and end surfaces of some of the conductive pillars 201. Then, a metallization layer 52 such as a chemically deposited copper layer (an electrolessly deposited copper layer), a sputtered titanium layer, or a sputtered copper layer is formed on the surface of the dielectric material 51 and in the plurality of fourth openings 510 by a chemical deposition process.

As shown in FIG. 5C, a first dry film photoresist layer 92a is formed on the metallization layer 52.

In one embodiment, a patterning process (such as a dry film process) is used to form the first dry film photoresist layer 92a on the metallization layer 52. The first dry film photoresist layer 92a is a patterned dry film photoresist layer having a plurality of fifth openings 923, so that portions of the metallization layer 52 are exposed from the first dry film photoresist layer 92a.

As shown in FIG. 5D, a patterned circuit layer 54 is electroplated on the surface of the metallization layer 52 in the plurality of fifth openings 923 of the first dry film photoresist layer 92a using a patterned exposure, development and electroplating process. At the same time, a plurality of conductive blind vias 55 are also formed on the surface of the metallization layer 52 in the plurality of fourth openings 510.

As shown in FIG. 5E, the carrying plate 9 and the bonding layer 91 are removed. Then, the first dry film photoresist layer 92a is removed by a stripping process, and the portions of the metallization layer 52 not covered by the patterned circuit layer 54 are removed by etching, thereby exposing portions of the surface of the dielectric material 51. Accordingly, a semiconductor package carrier structure 5 is completed. Specifically, the patterned circuit layer 54 comprises a die placement pad 54a corresponding to the die placement portion 202, and a plurality of bonding pads 54b corresponding to the plurality of conductive pillars 201. The die placement pad 54a is electrically connected to the die placement portion 202, and the plurality of bonding pads 54b are electrically connected to the plurality of conductive pillars 201.

In one embodiment, a surface treatment layer (not shown) may be formed entirely or selectively on one or both sides (i.e., on the conductive material of either or both of the opposing surfaces) of the substrate body 20 of the semiconductor package carrier structure 5. Examples of such surface treatments include electroless nickel electroless palladium immersion gold (ENEPIG), nickel/gold electroplating, pre-plating treatment (PPF), or an anti-oxidation layer.

As shown in FIG. 5F, the electronic element 8 is disposed on and bonded to the die placement pad 54a of the semiconductor package carrier structure 5, and the electronic element 8 is electrically connected to the plurality of bonding pads 54b by, for example, bonding wires 26. The packaging layer 25 is then formed on the semiconductor package carrier structure 5 to encapsulate the patterned circuit layer 54 and the electronic element 8, thereby completing a semiconductor package. The semiconductor package can also be completed by using a flip-chip packaging process.

In another embodiment, although the substrate body 20 is only disposed on one side of the carrying plate 9 in the first to fourth embodiments for subsequent processes, the substrate body 20 may be disposed on both sides of the carrying plate 9 for subsequent processes, thereby doubling the production capacity.

In this regard, the method for manufacturing the semiconductor package carrier structure 2, 3, 4, 5 of the present disclosure mainly utilizes a single-sided etching combined with a single-sided electroplating process to define a plurality of conductive pillars 201 and a die placement portion 202 having side surfaces in a concave arc shape 200a on the substrate body 20, and to form a patterned circuit layer 24, 34, 44, 54 on the substrate body 20, thereby obtaining a semiconductor package carrier structure 2, 3, 4, 5. Therefore, compared with the prior art, the present disclosure can improve the instability of the double-sided etched structure, and can greatly improve the yield of the semiconductor package carrier structure 2, 3, 4, 5, and effectively improve the extensiveness of product application design.

The present disclosure also provides a semiconductor package carrier structure 2, 3, 4, 5, which comprises: a substrate body 20, a dielectric material 21, 32, 51, a patterned circuit layer 24, 34, 44, 54, an electronic element 8, and a packaging layer 25.

The substrate body 20 having a first surface 20a and a second surface 20b opposite to the first surface 20a is made of a conductive material, and the substrate body 20 has a plurality of openings 200 penetrating through the substrate body 20 to define a plurality of conductive pillars 201 and at least one die placement portion 202, wherein the conductive pillars 201 are distributed around the die placement portion 202, and side surfaces of the plurality of conductive pillars 201 and the die placement portion 202 are in a concave arc shape 200a.

The dielectric material 21, 32, 51 is disposed in the plurality of openings 200, and portions of surfaces of the dielectric material 21, 32, 51 are exposed from the first surface 20a and the second surface 20b.

The patterned circuit layer 24, 34, 44, 54 is disposed on one of the first surface 20a or the second surface 20b of the substrate body 20, and the patterned circuit layer 24, 34, 44, 54 comprises a die placement pad 24a, 34a, 44a, 54a corresponding to the die placement portion 202 and a plurality of bonding pads 24b, 34b, 44b, 54b corresponding to the plurality of conductive pillars 201. The die placement pad 24a, 34a, 44a, 54a and the die placement portion 202 are electrically connected to each other, and some of the bonding pads 24b, 34b, 44b, 54b and some of the conductive pillars 201 are electrically connected to each other.

The electronic element 8 is disposed on the die placement pad 24a, 34a, 44a, 54a, and the electronic element 8 is electrically connected to the plurality of bonding pads 24b, 34b, 44b, 54b by, for example, bonding wires 26.

The packaging layer 25 is formed on the substrate body 20 and encapsulates the patterned circuit layer 24, 34, 44, 54 and the electronic element 8.

In one embodiment, a metallization layer 22, 31, 41, 52 is disposed between the die placement pad 24a, 34a, 44a, 54a and the die placement portion 202, between the bonding pads 24b, 34b, 44b, 54b and the conductive pillars 201, and between some of the bonding pads 24b, 34b, 44b, 54b and portions of the dielectric material 21, 32, 51, wherein the metallization layer 22, 31, 41, 52 is a chemically deposited copper layer (an electrolessly deposited copper layer).

In one embodiment, inner wall surfaces and bottom surfaces of the openings 200 of the substrate body 20 are formed with the metallization layer 31. The metallization layer 31 is at least one selected from a group consisting of a chemically deposited copper layer, a sputtered titanium layer, and a sputtered copper layer to cover the dielectric material 32. The metallization layer 31 in the plurality of openings 200 is located between the plurality of openings 200 and the dielectric material 32.

In one embodiment, the dielectric material 21 covers the first surface 20a or the second surface 20b of the substrate body 20, wherein the patterned circuit layer 44 is disposed on the dielectric material 21 of the first surface 20a or the second surface 20b of the substrate body 20, and portions of the patterned circuit layer 44 are electrically connected to the die placement portion 202 and the conductive pillars 201 via a plurality of conductive blind vias 55 embedded in the dielectric material 21. A metallization layer 41 is disposed between the patterned circuit layer 44 and the dielectric material 21, and on side surfaces and bottom surfaces of the conductive blind vias 55. The metallization layer 41 is at least one selected from the group consisting of a chemically deposited copper layer, a sputtered titanium layer, and a sputtered copper layer.

In one embodiment, the semiconductor package carrier structure 2, 3, 4, 5 further comprises a surface treatment layer (not shown) disposed on the patterned circuit layer 24, 34, 44, 54.

In the present disclosure, the conductive material forming the substrate body 20 is at least one selected from a group consisting of pure copper, copper alloy, and nickel alloy.

In one embodiment, the dielectric material 21, 32, 51 comprises a photosensitive organic dielectric material or a non-photosensitive organic dielectric material. In one embodiment, the dielectric material 21, 32, 51 is at least one selected from a group consisting of Ajinomoto build-up film (ABF), polybenzoxazole (PBO), polyimide (PI), prepreg (PP) with glass fibers, epoxy, epoxy molding compound (EMC), and bismaleimide triazine (BT).

To sum up, the method for manufacturing the semiconductor package carrier structure of the present disclosure mainly utilizes a single-sided etching combined with a single-sided electroplating process to define a plurality of conductive pillars and a die placement portion having side surfaces in a concave arc shape on the substrate body, and to form a patterned circuit layer, including a die placement pad corresponding to the die placement portion and a plurality of bonding pads corresponding to the plurality of conductive pillars, on the substrate body, thereby obtaining a substrate structure. Therefore, compared with the prior art, the present disclosure can improve the instability of the double-sided etched lead frame package carrier structure, and can greatly improve the yield of the semiconductor package carrier structure, and effectively improve the extensiveness of product application design.

The foregoing embodiments are provided for the purpose of illustrating the principles and effects of the present disclosure, rather than limiting the present disclosure. Anyone skilled in the art can modify and alter the above embodiments without departing from the spirit and scope of the present disclosure. Therefore, the scope of protection with regard to the present disclosure should be as defined in the accompanying claims listed below.

What is claimed is:

1. A semiconductor package carrier structure, comprising:
a substrate body being a plate body made of a conductive material and having a first surface and a second surface opposite to the first surface, wherein the substrate body has a plurality of openings formed by a one-time etching process from a single side and penetrating through the substrate body to define at least one die placement portion and a plurality of conductive pillars distributed around the die placement portion, wherein side surfaces of the die placement portion and the plurality of conductive pillars are in a concave arc shape;
a dielectric material formed in the plurality of openings, wherein portions of surfaces of the dielectric material are exposed from the first surface and the second surface; and
a patterned circuit layer disposed on one of the first surface or the second surface of the substrate body, wherein the patterned circuit layer comprises a die placement pad corresponding to the die placement portion and a plurality of bonding pads corresponding to the plurality of conductive pillars, wherein the die placement pad and the die placement portion are electrically connected to each other, and a portion of the plurality of bonding pads and a portion of the plurality of conductive pillars are electrically connected to each other.

2. The semiconductor package carrier structure of claim 1, further comprising: a metallization layer disposed between the die placement pad and the die placement portion, between the bonding pads and the conductive pillars, and between some of the plurality of bonding pads and the portions of the dielectric material, wherein the metallization layer is at least one selected from a group consisting of a chemically deposited copper layer, a sputtered titanium layer, and a sputtered copper layer.

3. The semiconductor package carrier structure of claim 1, further comprising: a metallization layer disposed between inner wall surfaces of the plurality of openings of the substrate body and the dielectric material, and between some of the plurality of bonding pads and the portions of the dielectric material, wherein the metallization layer is at least one selected from a group consisting of a chemically deposited copper layer, a sputtered titanium layer, and a sputtered copper layer.

4. The semiconductor package carrier structure of claim 1, wherein the dielectric material covers the first surface or the second surface of the substrate body, and the patterned circuit layer is disposed on the dielectric material of the first surface or the second surface of the substrate body, wherein portions of the patterned circuit layer are electrically connected to the die placement portion and the plurality of conductive pillars via a plurality of conductive blind vias embedded in the dielectric material, and a metallization layer is disposed between the patterned circuit layer and the dielectric material, and on side surfaces and bottom surfaces of the plurality of conductive blind vias, wherein the metallization layer is at least one selected from a group consisting of a chemically deposited copper layer, a sputtered titanium layer, and a sputtered copper layer.

5. The semiconductor package carrier structure of claim 1, further comprising: a surface treatment layer disposed on the patterned circuit layer.

6. The semiconductor package carrier structure of claim 1, wherein the conductive material forming the substrate body is at least one selected from a group consisting of pure copper, copper alloy, and nickel alloy.

7. The semiconductor package carrier structure of claim 1, wherein the dielectric material comprises a photosensitive organic dielectric material or a non-photosensitive organic dielectric material.

8. The semiconductor package carrier structure of claim 1, wherein the dielectric material is at least one selected from a group consisting of Ajinomoto build-up film, polybenzoxazole, polyimide, prepreg with glass fibers, epoxy, epoxy molding compound, and bismaleimide triazine.

9. The semiconductor package carrier structure of claim 1, further comprising:
at least one electronic element disposed on the die placement pad and electrically connected to the plurality of bonding pads; and
a packaging layer disposed on the substrate body and encapsulating the patterned circuit layer and the electronic element.

10. A method of manufacturing a semiconductor package carrier structure, comprising:
providing a substrate body, wherein the substrate body has a first surface and a second surface opposite to the first surface, and the substrate body is made of a conductive material;
bonding the second surface of the substrate body to a carrying plate;
forming, on the first surface of the substrate body, a plurality of openings penetrating through the substrate body by a one-time etching process from a single side using a patterned exposure, development and etching process to define at least one die placement portion and a plurality of conductive pillars distributed around the die placement portion, wherein side surfaces of the die placement portion and the plurality of conductive pillars are in a concave arc shape;
forming a dielectric material on the first surface of the substrate body to fill the plurality of openings and cover the first surface of the substrate body;
performing a planarization process to remove portions of the dielectric material to expose the first surface of the substrate body;
removing the carrying plate to expose the second surface of the substrate body and portions of a surface of the dielectric material; and
forming a patterned circuit layer by electroplating on the first surface or the second surface of the substrate body and the exposed surface of the dielectric material via a patterned exposure, development and electroplating process, wherein the patterned circuit layer comprises a die placement pad corresponding to the die placement portion and a plurality of bonding pads corresponding to the plurality of conductive pillars, wherein the die placement pad is electrically connected to the die placement portion, and the plurality of bonding pads are electrically connected to the plurality of conductive pillars.

11. The method of claim 10, wherein before performing the patterned exposure, development and electroplating process, the method further comprising:
forming a metallization layer on the first surface or the second surface of the substrate body and the exposed surface of the dielectric material by a chemical deposition process, wherein the metallization layer is at least one selected from a group consisting of a chemically deposited copper layer, a sputtered titanium layer, and a sputtered copper layer; and
performing an etching process after the patterned exposure, development and electroplating process is completed to form the patterned circuit layer on a surface of the metallization layer, so as to remove portions of the metallization layer that are not covered by the patterned circuit layer, thereby exposing portions of the first surface or the second surface and portions of a surface of the dielectric material.

12. The method of claim 10, wherein before forming the dielectric material, the method further comprising:
forming a metallization layer on the first surface of the substrate body and inner wall surfaces and bottom surfaces of the plurality of openings by a chemical deposition process, wherein the metallization layer is at least one selected from a group consisting of a chemically deposited copper layer, a sputtered titanium layer, and a sputtered copper layer; and
performing an etching process after the patterned exposure, development and electroplating process is completed on the metallization layer and the second surface, and the patterned circuit layer is formed on the metallization layer and the second surface, so as to remove portions of the metallization layer that are not covered by the patterned circuit layer and to remove portions of the conductive material on the second surface of the substrate body, thereby exposing portions of a surface of the dielectric material.

13. The method of claim 10, wherein performing the planarization process results in that the first surface of the substrate body is not exposed, and the method further comprising:
performing an opening process to remove portions of the dielectric material, so as to form a plurality of recessed openings on a surface of the dielectric material, wherein end surfaces of the die placement portion and the plurality of conductive pillars are exposed;
performing a chemical deposition process to form a metallization layer on the surface of the dielectric material and in the plurality of openings, wherein the metallization layer is at least one selected from a group consisting of a chemically deposited copper layer, a sputtered titanium layer, and a sputtered copper layer; and
performing an etching process after completing the patterned exposure, development and electroplating process to form the patterned circuit layer on the surface of the metallization layer and forming a plurality of conductive blind vias in the plurality of openings, so as to remove portions of the metallization layer that are not covered by the patterned circuit layer and expose portions of the surface of the dielectric material.

14. The method of claim 13, wherein the opening process includes laser removal, exposure and development removal, etching removal, plasma removal, or drilling removal to form the plurality of openings.

15. The method of claim 10, further comprising:
disposing and bonding an electronic element to the die placement pad, and electrically connecting the electronic element to the plurality of bonding pads; and
forming a packaging layer on the substrate body to encapsulate the patterned circuit layer and the electronic element.

16. The method of claim 10, further comprising: forming a surface treatment layer on the patterned circuit layer.

17. The method of claim 10, wherein the second surface of the substrate body is bonded to the carrying plate via a bonding layer, and the bonding layer is an adhesive layer having adhesive properties.
